(19) United States
(12) Patent Application Publication
(10) Pub. No.: US 2026/0144105 A1
(43) Pub. Date: May 21, 2026

(54) MEMORY PACKAGE AND STORAGE DEVICE INCLUDING THE SAME

(71) Applicant: Samsung Electronics Co., Ltd., Suwon-si (KR)

(72) Inventors: Kihong Jeong, Suwon-si (KR); Jooyeon Lee, Suwon-si (KR); Jiwoon Park, Suwon-si (KR); Heewoo An, Suwon-si (KR); Hyunsuk Jung, Suwon-si (KR)

(21) Appl. No.: 19/226,238

(22) Filed: Jun. 3, 2025

(30) Foreign Application Priority Data
Nov. 21, 2024 (KR) 10-2024-0167122

(51) Int. Cl. H01L 23/538; H01L 23/00; H01L 23/31; H01L 25/18

(52) U.S. Cl. CPC H10W 70/65; H10W 70/611; H10W 74/111; H10W 90/00; H10W 90/401; H10W 72/884; H10W 90/20; H10W 90/24; H10W 90/732; H10W 90/734; H10W 90/752; H10W 90/754

(57) ABSTRACT

A memory package includes a package substrate, memory chips disposed on the package substrate and grouped into first and second groups, the first and second groups being spaced apart from each other in a first horizontal direction, a first buffer chip disposed on the package substrate and outputting a control command signal received from an external memory controller to the first group, and a second buffer chip disposed on the package substrate and outputting the control command signal to the second group. The package substrate includes a main path transmitting the control command signal transmitted from the external memory controller, and a stub path connecting the main path to each of the first and buffer chips. The stub path branches the control command signal to the first and second buffer chips. The stub path is disposed in a space between the first and second buffer chips.

### CROSS-REFERENCE TO RELATED APPLICATION(S)

This application claims benefit of priority to Korean Patent Application No. 10-2024-0167122 filed on Nov. 21, 2024 in the Korean Intellectual Property Office, the disclosure of which is herein incorporated by reference in its entirety.

### BACKGROUND

The example embodiments relates to a memory package and a storage device including the same.

A memory package may include a plurality of memory chips mounted on a package substrate, and a storage device may include one or more memory packages. The storage device may include a device controller for controlling the memory package, and the device controller may control a plurality of memory chips through a buffer chip included in the memory package. As the demand for data storage in various electronic devices continues to grow, there is a rising need for memory packages and storage devices in which buffer chips and memory chips are efficiently arranged.

### SUMMARY

One of the problems to be solved by the example embodiments is to provide a memory package and a storage device, in which multiple memory chips are effectively connected using a connection layer of a package substrate and/or a system substrate.

According to an aspect of the present disclosure, a memory package includes a package substrate, a plurality of memory chips disposed on an upper surface of the package substrate and grouped into a first group of memory chips stacked in a vertical direction perpendicular to the upper surface of the package substrate and a second group of memory chips stacked in the vertical direction, wherein the first group of memory chips are spaced apart from the second group of memory chips in a first horizontal direction parallel to the upper surface of the package substrate, a first buffer chip disposed on the upper surface of the package substrate and configured to output a control command signal received from an external memory controller to the first group of memory chips, and a second buffer chip disposed on the upper surface of the package substrate and configured to output the control command signal to the second group of memory chips, wherein the first buffer chip and the second buffer chip are disposed in a space between the first group of memory chips and the second group of memory chips and arranged in the first horizontal direction. The package substrate includes a main path through which the control command signal is transmitted from the external memory controller, and a stub path connecting the main path to each of the first buffer chip and the second buffer chip. The stub path is configured to branch the control command signal received from the main path to the first buffer chip and the second buffer chip. The stub path, when view in a plan view, is disposed in a space between the first buffer chip and the second buffer chip.

According to an aspect of the present disclosure, a storage device includes a system substrate comprising a plurality of interconnections, a memory controller mounted on the system substrate, and at least one memory package mounted on the system substrate and configured to operate in response to a control command signal received from the memory controller through the plurality of interconnections, wherein the at least one memory package includes a plurality of memory chips, a pair of buffer chips adjacent to each other in a first horizontal direction parallel to an upper surface of the system substrate, connected to the memory controller and the plurality of memory chips, and configured to output the control command signal received from the memory controller to the plurality of memory chips, a package substrate including a plurality of connections electrically connected to the plurality of interconnections, and a plurality of upper bonding pads between the pair of buffer chips and electrically connected to the pair of buffer chips, wherein the plurality of memory chips and the pair of buffer chips are mounted on the package substrate, and a protective layer encapsulating the plurality of memory chips and the pair of buffer chips. The pair of buffer chips are connected to the memory controller through a single channel provided by the plurality of interconnections and the plurality of connections. The single channel comprises a main path connected to the memory controller, and a stub path extending from one end of the main path located between the pair of buffer chips and connected to each buffer chip of the pair of buffer chips. The stub path comprises a horizontal section extending from the one end of the main path in the first horizontal direction and having opposite ends respectively connected to corresponding upper bonding pads of the plurality of upper bonding pads. The one end of the main path is connected to a middle, in the first horizontal direction, of the opposite ends of the horizontal section of the stub path. The opposite ends of the horizontal section of the stub path are at the same vertical level in a vertical direction perpendicular to the upper surface of the system substrate.

According to an aspect of the present disclosure, a storage device includes a system substrate, a memory controller mounted on the system substrate, and at least one memory package mounted on the system substrate and configured to operate in response to a control command signal received from the memory controller. The at least one memory package includes a plurality of memory chips, a pair of buffer chips arranged adjacently to each other, connected to the memory controller and the plurality of memory chips, and configured to output the control command signal received from the memory controller to the plurality of memory chips, and a package substrate comprising a pair of upper bonding pads electrically connected to the pair of buffer chips. The memory chips and the pair of buffer chips are mounted on the package substrate. The pair of buffer chips are connected to the memory controller through a main path extending from the memory controller and a stub path extending from the main path. The stub path contacts the pair of upper bonding pads between the pair of buffer chips.

According to an aspect of the example embodiments, a storage device is provided, the storage device comprising: a system substrate comprising interconnections; a device controller mounted on the system substrate; and at least one memory package mounted on the system substrate and configured to operate in response to a control command received from the device controller through the interconnections, wherein the at least one memory package comprises: a plurality of memory chips; at least one pair of buffer chips arranged adjacently to each other, connected to the device controller and the plurality of memory chips and configured to output the control command input from the device controller to the plurality of memory chips; and a package substrate comprising connections electrically connected to the interconnections, wherein the plurality of memory chips and the pair of buffer chips are mounted on the package substrate, wherein the at least one pair of buffer chips is connected to the device controller through a stub path provided by the connections, and the stub path is located between one sides of the pair of buffer chips facing each other or between the other sides opposite the one sides, wherein the package substrate further comprises upper bonding pads arranged between the at least one pair of buffer chips, the connections comprise a connection pattern extending in a horizontal direction, and a connection via extending from the connection pattern to the upper bonding pads, and the connection pattern and the connection via provide the stub path, wherein the stub path comprises: a horizontal section provided by the connection pattern; and a vertical section provided by the connection via, and extending from opposite ends of the horizontal section to the upper bonding pads.

### BRIEF DESCRIPTION OF DRAWINGS

The above and other aspects, features, and advantages of the example embodiments will be more clearly understood from the following detailed description, taken in conjunction with the accompanying drawings, in which:

FIGS. 1 and 2 are schematic diagrams of storage devices according to example embodiments of the example embodiments;

FIG. 3 is a schematic circuit diagram of a memory cell array according to an example embodiment;

FIG. 4 is a schematic diagram of an external appearance of a storage device according to an example embodiment;

FIG. 5 is a cross-sectional side view of a storage device according to an example embodiment;

FIG. 6 is a schematic diagram of an external appearance of a storage device according to an example embodiment;

FIGS. 7A and 7B are cross-sectional side views of a storage device according to an example embodiment;

FIG. 8 is a schematic diagram of buffer chips according to an example embodiment;

FIG. 9 is a cross-sectional side view of a memory package according to an example embodiment;

FIG. 10 is a cross-sectional side view of a memory package according to an example embodiment;

FIG. 11 is a cross-sectional side view of a memory package according to an example embodiment;

FIG. 12 is a cross-sectional side view of a memory package according to an example embodiment;

FIG. 13 is a cross-sectional side view of a memory package according to an example embodiment;

FIG. 14 is a cross-sectional side view of a memory package according to an example embodiment; and

FIG. 15 is a cross-sectional side view of a memory package according to an example embodiment.

### DETAILED DESCRIPTION

Hereinafter, embodiments of the example embodiments will be described with reference to the attached drawings. Unless otherwise specifically stated, in this specification, terms such as “upper,” “an upper surface,” “lower,” “a lower surface,” “a side surface,” and the like are based on the drawings, and may actually vary depending on a direction in which a component is arranged.

In addition, ordinal numbers such as “first,” “second,” “third,” and the like may be used as labels for specific elements, steps, directions, and the like to distinguish various elements, steps, directions, etc. Terms not described using “first,” “second,” etc. in the specification may still be referred to as “first” or “second” in the claims. In addition, terms referenced by a specific ordinal number (e.g., “first” in a particular claim) may be described elsewhere with a different ordinal number (e.g., “second” in the specification or another claim).

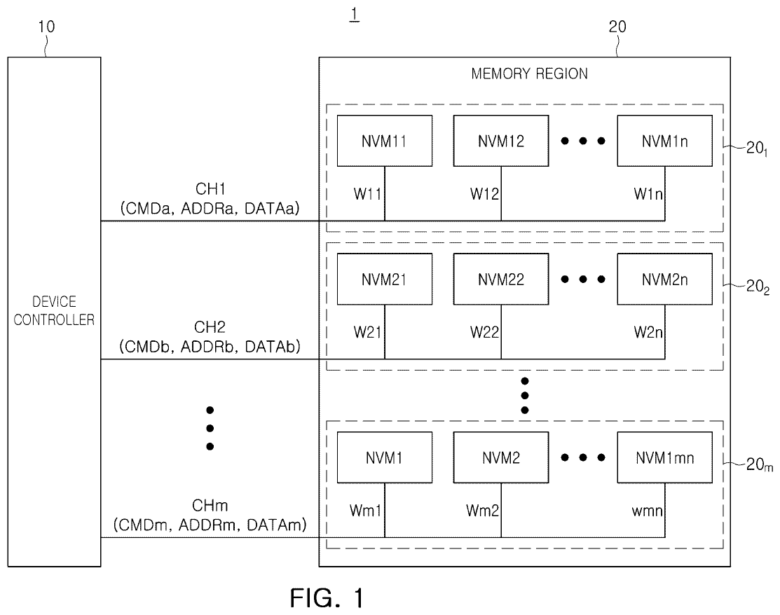

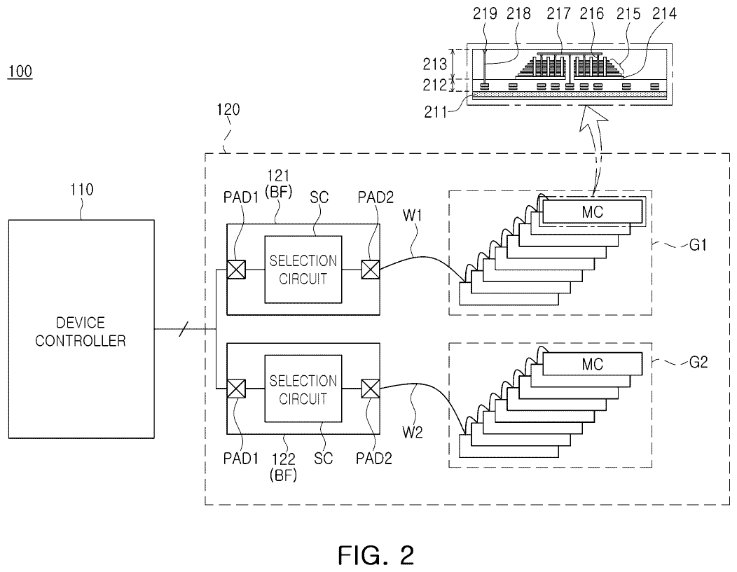

FIG. 1 and FIG. 2 are schematic diagrams of storage devices 1 and 100 according to an example embodiment of the example embodiments.

First, referring to FIG. 1, the storage device 1 may include a device controller 10 and a memory region 20. The device controller 10 may be a memory controller for controlling operations of the memory region 20. The storage device 1 may support a plurality of channels CH1 to CHm, and the memory region 20 and the device controller 10 may be connected through the plurality of channels CH1 to CHm. For example, the storage device 1 may include a solid-state drive (SSD) device, etc.

The memory region 20 may include a plurality of memory packages 20₁ to 20ₘ. The plurality of memory packages 20₁ to 20ₘ may be connected to the device controller 10 through the plurality of channels CH1 to CHm, and each of the plurality of memory packages 20₁ to 20ₘ may include a plurality of memory devices NVM11 to NVMmn. Each of the plurality of memory devices NVM11 to NVMmn may be connected to one of the plurality of channels CH1 to CHm through a corresponding way. For example, the memory devices NVM11 to NVM1n included in a first memory package 20₁ may be connected to a first channel CH1 through the ways W11 to W1n, and the memory devices NVM21 to NVM2n included in a second memory package 20₂ may be connected to a second channel CH2 via the ways W21 to W2n.

In an example embodiment, each of the plurality of memory devices NVM11 to NVMmn may be implemented in an arbitrary memory unit that may operate according to an individual command from the device controller 10. For example, each of the plurality of memory devices NVM11 to NVMmn may be implemented as a chip or a die. However, the example embodiment is not limited thereto. When each of the plurality of memory devices NVM11 to NVMmn is implemented as a chip or die, the plurality of memory devices NVM11 to NVMmn may be stacked on each other in the plurality of memory packages 20₁ to 20ₘ, respectively.

The device controller 10 may transmit or receive signals to or from the memory region 20 through the plurality of channels CH1 to CHm. For example, the device controller 10 may transmit commands CMDa to CMDm, addresses ADDRa to ADDRm, and data DATAa to DATAm to the memory region 20 or receive the data DATAa to DATAm from the memory region 20, through the plurality of channels CH1 to CHm.

In an embodiment, the plurality of memory packages 20₁ to 20ₘ may include a buffer chip, and the buffer chip may transmit signals between the plurality of memory devices NVM11 to NVMmn and the device controller 10. For example, in a program operation, the device controller 10 may transmit data to be stored in the memory region 20 and an address signal to the buffer chip. The buffer chip may transmit data to one of the plurality of memory devices NVM11 to NVMmn based on the address signal.

When the plurality of memory packages 20₁ to 20ₘ include the buffer chip, the buffer chip may output data and address signals to at least one of the plurality of memory devices NVM11 to NVMmn based on the data and address signals transmitted by the device controller 10 to the buffer chip. In other words, the buffer chip may branch and provide a signal transmission path between the device controller 10 and the plurality of memory devices NVM11 to NVMmn.

The device controller 10 may select one of nonvolatile memory devices connected to each channel through that channel, and transmit or receive signals to or from the selected nonvolatile memory device. For example, the device controller 10 may select a nonvolatile memory device NVM11 of the nonvolatile memory devices NVM11 to NVM1n connected to the first channel CH1. The device controller 10 may transmit a command CMDa, an address ADDRa, and data DATAa to the selected nonvolatile memory device NVM11 through the first channel CH1, or may receive the data DATAa from the selected nonvolatile memory device NVM11.

The device controller 10 may transmit or receive signals in parallel to or from the memory region 20 through different channels. For example, the device controller 10 may transmit the command CMDa to the first memory package 20₁ through the first channel CH1, while transmitting a command CMDb to the second memory package 20₂ through the second channel CH2. For this purpose, each of the first memory package 20₁ and the second memory package 20₂ may include a buffer chip. Alternatively, the device controller 10 may receive the data DATAa from the first memory package 20₁ through the first channel CH1, while receiving data DATAb from the second memory package 20₂ through the second channel CH2.

The device controller 10 may control the overall operations of the memory region 20. The device controller 10 may control each of the plurality of memory devices NVM11 to NVMmn connected to the plurality of channels CH1 to CHm by transmitting signals to the plurality of channels CH1 to CHm. For example, the device controller 10 may control a selected one of the plurality of memory devices NVM11 to NVM1n by transmitting the command CMDa and the address ADDRa to the first channel CH1.

Each of the plurality of memory devices NVM11 to NVMmn may operate under a control of the device controller 10. For example, the memory device NVM11 may program the data DATAa according to the command CMDa, the address ADDRa, and the data DATAa provided through the first channel CH1. For example, the memory device NVM21 may read the data DATAb based on the command CMDb and the address ADDRb provided through the second channel CH2 and transmit the read data DATAb to the device controller 10.

FIG. 1 illustrates that the memory region 20 communicates with the device controller 10 through m channels, and the memory region 20 includes n nonvolatile memory devices corresponding to each channel. However, the number of channels and the number of memory devices connected to one channel may vary.

Referring to FIG. 2, the storage device 100 of the example embodiment may include a device controller 110 and a memory package 120. The memory package 120 may include a pair of buffer chips BF and a plurality of memory chips MC, and the plurality of memory chips MC may be divided into a plurality of groups G1 and G2. In the embodiment illustrated in FIG. 2, the number of memory chips MC included in each of the groups G1 and G2 is described as being the same, but the number of memory chips MC included in at least some of the groups G1 and G2 may be different from each other.

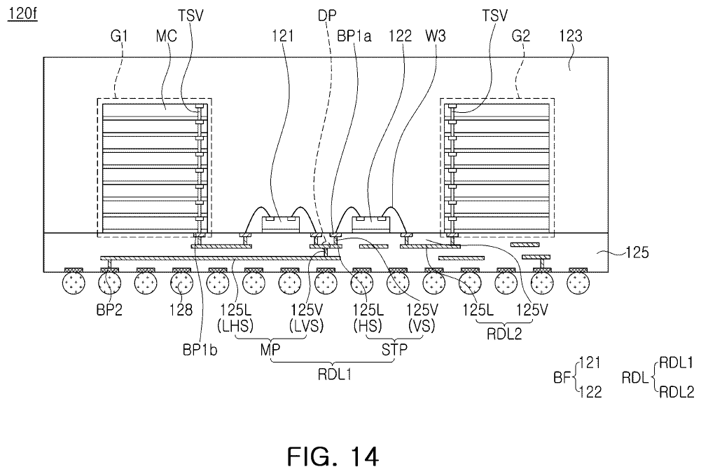

The memory chips MC included in each of the plurality of groups G1 and G2 may be connected to the pair of buffer chips BF through different paths, respectively. For example, a plurality of memory chips included in a first group G1 may be connected with each other through a first wire W1, and may also be connected to a first buffer chip 121. A plurality of memory chips included in a second group G2 may be connected with each other through a second wire W2, and may also be connected to a second buffer chip 122. Although briefly illustrated in FIG. 2, a plurality of first wires W1 and a plurality of second wires W2 may be provided to connect the first group G1 and the second group G2 to the buffer chips BF, respectively. In addition, according to embodiments, the memory chips may be connected with each other, or the memory chips MC may be connected to the buffer chip BF, by other connecting means than the wires W1 and W2. As an example, the memory chips of the first group G1 may be connected with each other through a through silicon via TSV, and may be connected to the first buffer chip 121 through the first wire W1 (the embodiment of FIG. 14).

The buffer chip BF may be a chip that mediates signal exchange between the device controller 110 and the memory package 120. The buffer chip BF may be connected to the wires W1 and W2 through a plurality of chip pads PAD1 and PAD2. The plurality of chip pads PAD1 and PAD2 are connected to a selection circuit SC, and the selection circuit SC may select at least one of the plurality of chip pads PAD1 and PAD2 according to a command from the device controller 110. In FIG. 2, the buffer chip BF is illustrated as including one controller connection pad PAD1 and one memory connection pad PAD2, but the controller connection pad PAD1 and the memory connection pad PAD2 may be provided in plural, respectively.

As an example, the device controller 110 may transmit an address signal for selecting at least one of the memory chips MC included in the first group G1 and the memory chips MC included in the second group G2 to the controller connection pad PAD1 of the buffer chip BF. The buffer chip BF may select the memory connection pad PAD2 and transmit data to the memory chips or receive data output by the memory chips, based on the address signal. If the storage device 100 supports a multi-channel operation for reducing latency, the address signal generated by the device controller 110 and the control command corresponding thereto may be simultaneously transmitted to the first group G1 and the second group G2.

For example, if the device controller 110 generates a control command to execute a control operation such as a program operation, a read operation or the like, the control command may include address information that specifies a memory chip for executing the control operation. The selection circuit SC of the buffer chip BF may select at least one of the plurality of memory access pads PAD2 and not select the remainder thereof, based on address information included in the control command.

According to embodiments, at least one of a transmitter for sending data and/or signals to the memory chips and a receiver for receiving data from the memory chip may be connected to each of the plurality of chip pads PAD1 and PAD2. The selection circuit SC may select at least one of the plurality of chip pads PAD1 and PAD2 based on the address information received from the device controller 110, and may activate the transmitter and/or the receiver connected to the selected at least one chip pad. In addition, the selection circuit SC may deactivate the transmitter and the receiver connected to a chip pad that is not selected from the plurality of chip pads PAD1 and PAD2.

As an example, the selection circuit SC may include a multiplexer or a demultiplexer. Therefore, the selection circuit SC may selectively transmit data and signals received from the device controller 110 to a plurality of memory chips divided into N groups (N is a natural number greater than or equal to 2).

Each of the memory chips MC may include a semiconductor substrate 211, and first and second structures 212 and 213 stacked on the semiconductor substrate 211. As an example, the first structure 212 may include a peripheral circuit region where peripheral circuits necessary for the operation of each of the memory chips MC, such as a row decoder, a page buffer, a voltage generator and the like, are arranged. The second structure 213 may include a cell region where a common source line 214, a gate stacked structure 215 having gate electrode layers stacked on the common source line 214, channel structures 216 penetrating the gate stacked structure 215, or bit lines 217 electrically connected to the channel structures 216 are arranged.

Each of the memory chips MC may include a through interconnection 218 connected to the peripheral circuits in the first structure 212 and extending in the second structure 213. The through interconnection 218 may be connected to an input/output pad 219 that is arranged above each of the memory chips MC. The input/output pad 219 of each of the memory chips MC included in the first group G1 may be connected to the first wire W1, and the input/output pad 219 of each of the memory chips MC included in the second group G2 may be connected to the second wire W2. Accordingly, the memory chips MC included in each of the first group G1 and the second group G2 may be electrically connected with each other.

Referring to FIG. 2, which illustrates a cross-sectional view, the through interconnection 218 of the memory chips MC is illustrated as one, but each of the memory chips MC may include a plurality of through interconnections. The plurality of through interconnections may be connected to a plurality of first wires through a plurality of input/output pads.

In an embodiment of the example embodiments, the memory package 120 may include buffer chips BF corresponding to the groups G1 and G2 of the memory chips MC, respectively, and the buffer chips BF may be connected to the device controller 110 through the same channel. Accordingly, a stub path between the device controller 110 and the buffer chips BF may be minimized, and signal reflection and RC delay may be minimized.

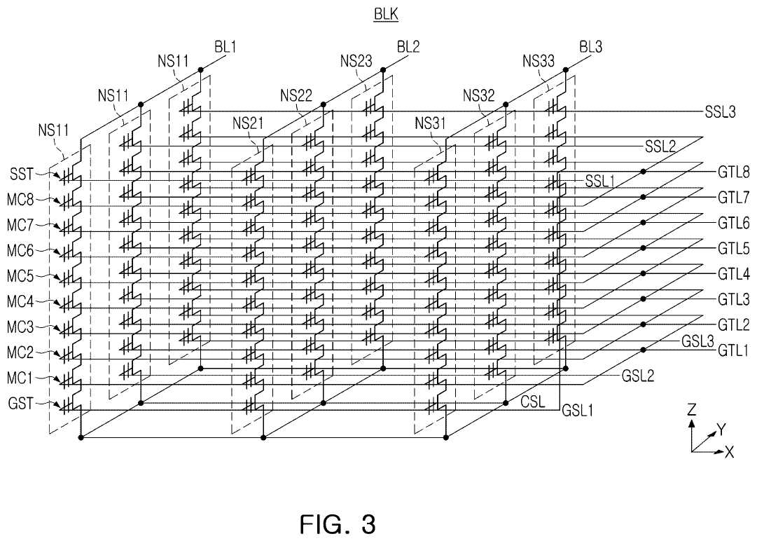

FIG. 3 is a schematic circuit diagram of a memory cell array according to an example embodiment.

FIG. 3 is a drawing for illustrating a 3D V-NAND structure that may be applied to a memory package according to an embodiment of the example embodiments. When the memory devices included in the memory package are implemented as flash memories of the 3D V-NAND type, each of the plurality of memory blocks constituting the memory devices may be expressed by an equivalent circuit as illustrated in FIG. 3.

The memory block BLK illustrated in FIG. 3 represents a three-dimensional memory block formed in a three-dimensional structure on a substrate. For example, a plurality of memory NAND strings included in the memory block BLK may be formed in a direction perpendicular to the substrate.

Referring to FIG. 3, the memory block BLK may include a plurality of memory NAND strings NS11 to NS33 connected between bit lines BL1, BL2 and BL3 and a common source line CSL. Each of the plurality of memory NAND strings NS11 to NS33 may include a string select transistor SST, a plurality of memory cells MC1, MC2, . . . and MC8, and a ground select transistor GST. Although FIG. 3 illustrates that each of the plurality of memory NAND strings NS11 to NS33 includes eight memory cells MC1, MC2, . . . and MC8, the example embodiment is not necessarily limited thereto.

The string select transistor SST may be connected to the corresponding string select line SSL1, SSL2 or SSL3. The plurality of memory cells MC1, MC2, . . . and MC8 may be connected to the corresponding gate line GTL1, GTL2, . . . and GTL8, respectively. The gate lines GTL1, GTL2, . . . and GTL8 may correspond to word lines, and some of the gate lines GTL1, GTL2, . . . and GTL8 may correspond to dummy word lines. The ground select transistor GST may be connected to the corresponding ground select line GSL1, GSL2 or GSL3. The string select transistor SST may be connected to the corresponding bit line BL1, BL2 and BL3, and the ground select transistor GST may be connected to the common source line CSL.

Word lines of the same height (e.g., WL1) may be commonly connected, and the ground selection lines GSL1, GSL2 and GSL3 and the string selection lines SSL1, SSL2 and SSL3 may be separated, respectively. In FIG. 3, the memory block BLK is illustrated as being connected to eight gate lines GTL1, GTL2, . . . and GTL8 and three bit lines BL1, BL2 and BL3, but the present inventive step is not necessarily limited thereto.

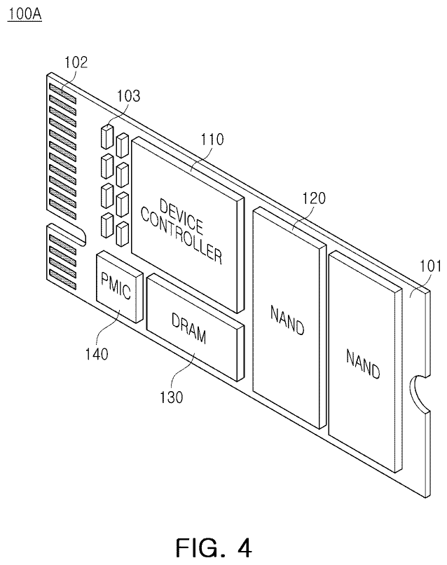

FIG. 4 is a schematic diagram of an external appearance of a storage device 100A according to an example embodiment. Hereinafter, in the detailed description and claims, ‘a storage device’ may be referred to as ‘a memory package’ further including a system substrate 101 and/or a device controller 110.

Referring to FIG. 4, the storage device 100A of the example embodiment may be a solid-state drive SSD. The storage device 100A may have a form factor according to the M.2 standard, and may communicate with an external central processing unit, a system-on-chip, or an application processor according to the PCIe (Peripheral Component Interconnect Express) protocol. However, the form factor of the storage device 100A and the protocol for communicating with other external devices may vary according to embodiments. For example, the storage device 100A may have a form factor such as a 2.5-inch disk drive, and may communicate with other external devices according to the SATA (Serial Advanced Technology Attachment) protocol.

The storage device 100A may include a system substrate 101, connector pins 102 and component elements 103 formed on the system substrate 101, a device controller 110, memory packages 120, or a DRAM 130 and a PMIC 140 mounted on the system substrate 101. The connector pins 102 may contact pins of a computer device and/or a server device on which the storage device 100A is mounted. The component elements 103 may include passive elements such as resistors and capacitors required for the operation of the storage device 100A.

The device controller 110 may control the storage device 100A according to a control command from the computer device and/or the server device. The device controller 110 may store data received through the connector pins 102 in the memory packages 120 and/or the DRAM 130, or may read data stored in the memory packages 120 and/or the DRAM 130 and output it to the computer device and/or the server device. The PMIC 140 may distribute power supplied through the connector pins 102 to the device controller 110, the memory packages 120, or the DRAM 130.

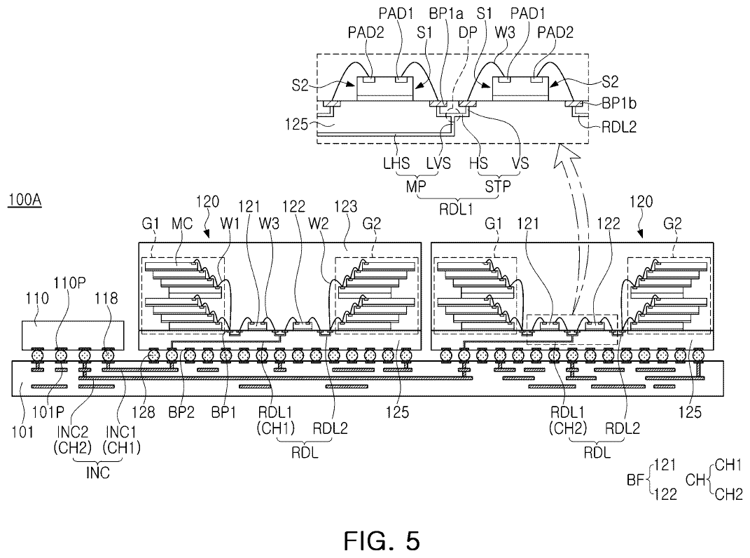

The memory packages 120 may be respectively implemented as memory packages according to the embodiments described below. For example, each of the memory packages 120 may include at least one pair of buffer chips and a plurality of memory chips. The pair of buffer chips may be arranged such that the controller connection pads face each other (0 degrees and 180 degrees). In addition, one of the buffer chips may include a data mirroring function. This will be described in more detail below with reference to FIG. 5.

FIG. 5 is a cross-sectional side view of a storage device 100A according to an example embodiment.

Referring to FIG. 5, the storage device 100A of the example embodiment may include at least one memory package 120, a device controller 110 and a system substrate 101.

The system substrate 101 may include interconnection pads 101P and interconnections INC. The interconnections INC may be connected to the device controller 110 and the memory package 120 through the interconnection pads 101P. The device controller 110 may be mounted on the interconnection pads 101P through chip bumps 118, and the memory packages 120 may be mounted on the interconnection pads 101P through the package bumps 128. The device controller 110 and the memory packages 120 may be electrically connected with each other through the interconnections INC formed inside the system substrate 101 and may exchange signals with each other. The interconnections INC may include an interconnection pattern portion and an interconnection via portion made of a conductive material.

In an example embodiment, signals generated by the device controller 110 to control the memory packages 120 and data to be stored in the memory chips MC inside the memory packages 120 may be transmitted to the memory packages 120 through channels CH1 and CH2 provided by the interconnections INC. For example, the device controller 110 may communicate with the memory packages 120 mounted on the system substrate 101 through the first channel CH1 provided by first interconnections INC1 and the second channel CH2 provided by second interconnections INC2, respectively. According to an example embodiment, the device controller 110 may communicate with the memory packages 120 each including a plurality of buffer chips BF through a single channel. For example, the plurality of buffer chips BF may share the single channel. As a result, a stub path length of the channel may be reduced, and SI (Signal Integrity) characteristics of the storage device may be improved.

The memory packages 120 may be configured to operate in response to a control command received from the device controller 110 through the interconnections INC of the system substrate 101. The memory packages 120 may include a plurality of memory chips MC, at least one pair of buffer chips BF, and a package substrate 125. The buffer chip BF and the plurality of memory chips MC may be covered with a protective layer 123 above the package substrate 125. The protective layer 123 may encapsulate the plurality of memory chips MC and the buffer chips BF, and may include an insulating material such as an epoxy molding compound EMC.

The plurality of memory chips MC are divided into a plurality of groups G1 and G2 and connected to a buffer chip BF, and the buffer chip BF may assign channels to the plurality of groups G1 and G2 to mediate signal transmission and reception between the device controller 110 and the plurality of memory chips MC. As an example, the memory chips MC of the first and second groups G1 and G2 may be connected to the first buffer chip 121 and the second buffer chip 122, respectively. The memory chips MC in each of the plurality of groups G1 and G2 may be stacked on each other and connected with each other by wires W1 and W2. Semiconductor chips of the first group G1 may be connected to the first buffer chip 121 through a first wire W1, and semiconductor chips of the second group G2 may be connected to the second buffer chip 122 through a second wire W2. However, according to embodiments, the memory chips MC included in each of the plurality of groups G1 and G2 may be connected with each other by through interconnections such as through silicon vias instead of wires.

The buffer chip BF may be a chip that mediates signal exchange between the device controller 110 and the memory chips MC. For example, the buffer chip BF may function as an intermediary for signal exchange between the device controller 110 and the memory chips MC. The buffer chip BF may be connected to the device controller 110 and the plurality of memory chips MC and configured to output a control command received from the device controller 110 to the plurality of memory chips MC. The buffer chip BF may be connected to the device controller 110 and the memory chips MC through a controller connection pad PAD1 and a memory connection pad PAD2. The controller connection pad PAD1 and the memory connection pad PAD2 may be connected to a first upper bonding pad BP1a and a second upper bonding pad BP1b through a third wire W3. In some embodiments, the buffer chip BF may be flip-chip bonded on the package substrate 125. The buffer chip BF may select at least one of a plurality of memory connection pads PAD2 according to a command from the device controller 110. For example, the device controller 110 may transmit an address signal for selecting at least some of the memory chips MC included in the first group G1 and/or at least some of the memory chips MC included in the second group G2 to the controller connection pad PAD1 of the buffer chip BF. Based on the address signal, the buffer chip BF may select the memory connection pad PAD2 and transmit data to the memory chips or receive data output by the memory chips.

The package substrate 125 may include bonding pads BP1 and BP2 and connections RDL. The connections RDL may be electrically connected to the buffer chip BF, the memory chips MC, and the device controller 110 through upper bonding pads BP1 and lower bonding pads BP2. The connections RDL may provide signal paths between the device controller 110 outside the package and the buffer chip BF, and/or signal paths between the buffer chip BF and the memory chips MC. Some of the connections RDL, for example, a first connections RDL1, may connect the first upper bonding pad BP1a to a lower bonding pad BP2 and provide a signal path for exchanging signals between the external device controller 110 and the buffer chip BF through the package bumps 128. The first connection RDL1 may provide a signal path between the device controller 110 and the buffer chip BF. Some of the connection RDL, for example, a second connection RDL2, may connect the second upper bonding pad BP1b to the memory chips MC and may provide a signal path for the memory chips MC and the buffer chip BF to exchange signals. The second connections RDL2 may provide a signal path between the buffer chip BF and the memory chips MC.

The package bumps 128 may be formed on the lower bonding pads BP2. The package bumps 128 may be connected to chip pads 110P and the chip bumps 118 of the device controller 110 through the interconnection pads 101P and the interconnections INC of the system substrate 101. The second connection RDL2 may be electrically separated from the package bumps 128. The second connection RDL2 may connect the memory chips MC in the memory package 120 to the corresponding buffer chips BF. Therefore, the second connection RDL2 may not be electrically connected to the package bumps 128 that connect the memory package 120 to the system substrate 101 and other components mounted on the system substrate 101, such as the device controller 110.

According to an example embodiment, the memory package 120 may include buffer chips BF corresponding to the groups G1 and G2 of the memory chips MC, respectively. The buffer chips BF mounted in one memory package 120 may communicate with the device controller 110 through the same channel, and may be arranged adjacently so that the controller connection pads PAD1 of the buffer chips BF face each other. For example, two memory packages 120 mounted on the system substrate 101 may communicate with the device controller 110 through a first channel CH1 and a second channel CH2, respectively. For example, a pair of buffer chips BF embedded in one of the two memory packages 120 may communicate with the device controller 110 through the first channel CH1, and a pair of buffer chips BF embedded in the other of the two memory packages 120 may communicate with the device controller 110 through the second channel CH2. Accordingly, a stub length of the signal transmission path (single channel) between the device controller 110 and the buffer chips BF may be reduced, and signal reflection and RC delay may be minimized.

For example, the memory package 120 may include a first buffer chip 121 that mediates signal exchange between memory chips of a first group G1 and a device controller 110, and a second buffer chip 122 that mediates signal exchange between memory chips of a second group G2 and the device controller 110. The first buffer chip 121 and the second buffer chip 122 may be connected to the first connections RDL1 through first upper bonding pads BP1a that are arranged between the first buffer chip 121 and the second buffer chip 122 among the upper bonding pads BP1. The first buffer chip 121 may transmit a first control signal branched from a control command signal received from the device controller 110 at a branch point DP to the first group G1, and the second buffer chip 122 may transmit a second control signal branched from the control command signal at the branch point DP to the second group G2.

The first connections RDL1 may include a main path MP (i.e., a main signal line) and a stub path STP (i.e., a stub signal line). The main path MP may be provided by the interconnections INC of the system substrate 101 and the connections RDL of the package substrate 125. The main path MP may extend from the device controller 110 to the interior of the package substrate 125. The main path MP may have one end (‘branch point’) DP at which a control command generated from the device controller 110 is branched into a pair of buffer chips BF. The branch point DP may be located on the connections RDL of the package substrate 125. The stub path STP may be connected to the first upper bonding pads BP1a between the pair of buffer chips BF. The stub path STP may connect the pair of buffer chips BF to the device controller 110. The stub path STP may be located between one sides S1 of the pair of buffer chips BF facing each other or between the other sides S2 of the pair of buffer chips BF opposite to the one sides S1. In an embodiment, the stub path STP connected to each of the first buffer chip 121 and the second buffer chip 122 may be formed only between the pair of buffer chips BF.

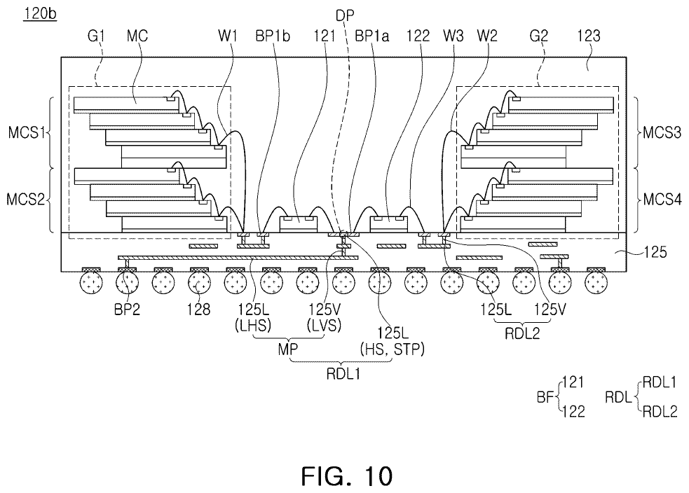

In an embodiment, the stub path STP may include a horizontal section HS and vertical sections VS. The horizontal section HS may extend horizontally from the branch point DP and may have opposite ends connected to the corresponding first upper bonding pads BP1a, respectively. The vertical sections VS may extend vertically from the opposite ends of the horizontal section HS to the corresponding first upper bonding pads BP1a. In some embodiments, the stub path STP may include only the horizontal section HS (the embodiment of FIG. 10). The opposite ends of the horizontal section HS may be located at the same vertical level. The main path MP may include a lower horizontal section LHS located below the horizontal section HS of the stub path STP, and a lower vertical section LVS connecting the lower horizontal section LHS of the main path MP to the horizontal section HS of the stub path STP. The branch point DP of the main path MP may be defined as a contact region between the lower vertical section LVS and the horizontal section HS (i.e., a contact region at which the lower vertical section LVS is connected to or contacts the horizontal section HS). The branch point DP may be located in the middle of the opposite ends of the horizontal section HS. For example, the length of the stub path STP from the branch point DP to the corresponding first upper bonding pads BP1a may be constant. For example, when viewed in a plan view, a length of the stub path between the branch point DP and one of the corresponding first upper bonding pads BP1a may be the same as a length of the stub path between the branch point DP and the other of the corresponding first upper bonding pads BP1a.

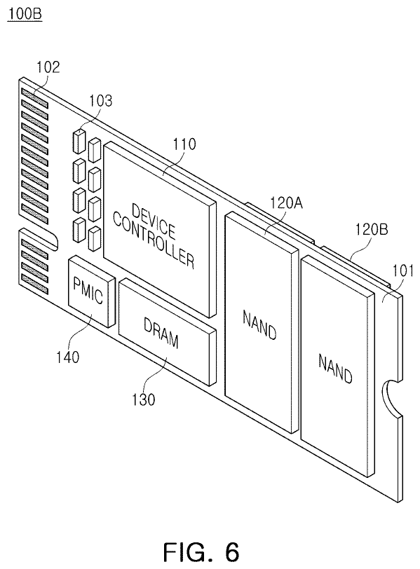

FIG. 6 is a schematic diagram of an external appearance of a storage device 100B according to an example embodiment.

Referring to FIG. 6, the storage device 100B of the example embodiment may have the same or similar features as those described with reference to FIG. 4, except that memory packages 120A and 120B are mounted on both sides of the system substrate 101. The storage device 100B may be a solid-state drive (SSD), similar to the embodiment described with reference to FIG. 4. The storage device 100B may communicate with an external central processing unit, a system-on-chip, or an application processor and the form factor of the storage device 100B and the protocol for communicating with the external device may be variously modified.

The storage device 100B may include a system substrate 101, connector pins 102 and component elements 103 formed on the system substrate 101, a device controller 110, the memory packages 120A and 120B, or a DRAM 130 and a PMIC 140 mounted on the system substrate 101.

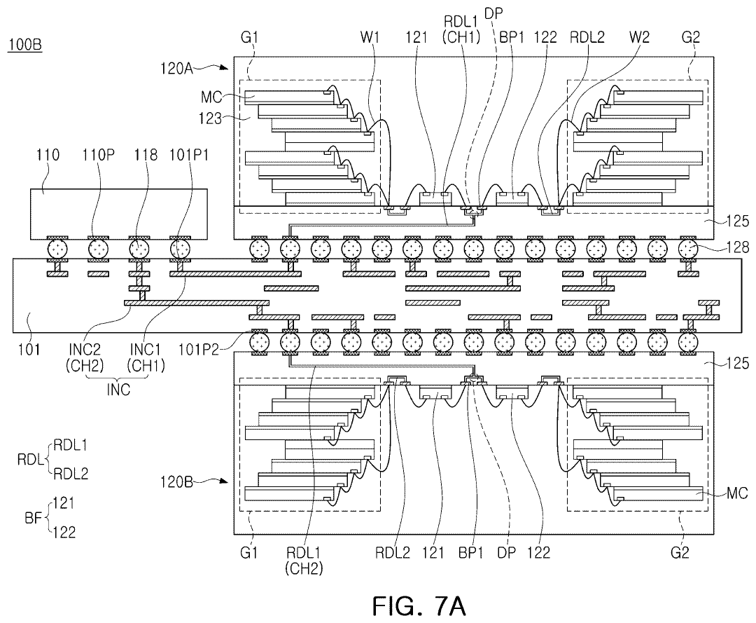

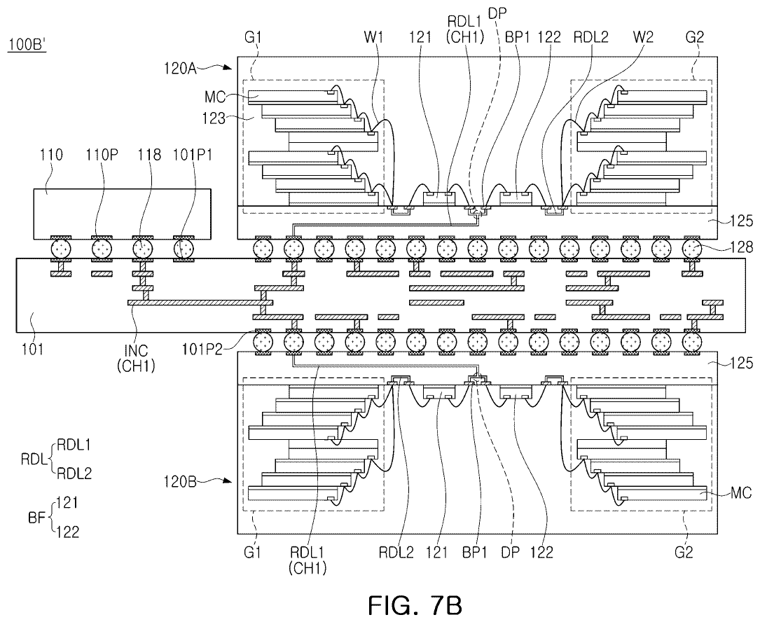

A capacity of the storage device 100B may be increased by mounting the memory packages 120A and 120B on both sides of the system substrate 101. According to example embodiments, each of the memory packages 120A and 120B may also include at least one pair of buffer chips. Hereinafter, this will be described in more detail with reference to FIGS. 7A and 7B.

FIGS. 7A and 7B are cross-sectional side views of the storage device 100B and 100B′ according to example embodiments, respectively.

Referring to FIG. 7A, the storage device 100B of the example embodiment may have the same or similar features as described with reference to FIG. 5, except that memory packages 120A and 120B are mounted on opposite sides (e.g., an upper surface and a lower surface) of the system substrate 101. The storage device 100B of the example embodiment may include at least one first memory package 120A and at least one second memory package 120B mounted on the opposite sides of the system substrate 101, respectively. The storage device 100B may further include a device controller 110 and a system substrate 101.

The system substrate 101 may include first interconnection pads 101P1, second interconnection pads 101P2, and interconnections INC. The interconnections INC may be connected to the device controller 110 and the memory packages 120A and 120B through the interconnection pads 101P1 and 101P 2. The device controller 110 may be mounted on the first interconnection pads 101P1 through chip bumps 118, and the first and second memory packages 120A and 120B may be mounted on the first and second interconnection pads 101P1 and 101P2 through package bumps 128, respectively. The device controller 110 and the memory packages 120A and 120B may be electrically connected with each other through the interconnections INC formed inside the system substrate 101 to exchange signals. The interconnections INC may include an interconnection pattern portion and an interconnection via portion made of a conductive material.

The device controller 110 and the memory packages 120A and 120B may be electrically connected with each other through the interconnections INC of the system substrate 101 to exchange signals. According to an example embodiment, the device controller 110 may communicate with the memory packages 120A and 120B each including a plurality of buffer chips BF through a single channel. For example, the device controller 110 may communicate with the first memory package 120A through a first channel CH1 provided by first interconnections INC1 and may communicate with the second memory package 120B through second channel CH2 provided by second interconnections INC2. As a result, a stub path length of the channel may be reduced, and SI (Signal Integrity) characteristics of the storage device may be improved.

The memory packages 120A and 120B may have the same configuration. The memory packages 120A and 120B may include a plurality of memory chips MC, at least one pair of buffer chips BF, and a package substrate 125. The buffer chips BF and the plurality of memory chips MC may be covered with a protective layer 123 above the package substrate 125.

The plurality of memory chips MC may be divided into a plurality of groups G1 and G2 and connected to the buffer chips BF including a first buffer chip 121 and a second buffer chip 122, and the buffer chips BF may assign channels to the plurality of groups G1 and G2 to mediate signal transmission and reception between the device controller 110 and the plurality of memory chips MC. As an example, the memory chips MC of the first and second groups G1 and G2 may be connected to the first buffer chip 121 and the second buffer chip 122, respectively. In each of the plurality of groups G1 and G2, the memory chips MC may be vertically stacked on each other and be connected with each other by wires W1 and W2. Semiconductor chips of the first group G1 may be connected to the first buffer chip 121 through a first wire W1, and semiconductor chips of the second group G2 may be connected to the second buffer chip 122 through a second wire W2. However, according to embodiments, the memory chips MC included in each of the plurality of groups G1 and G2 may be connected with each other by through interconnections such as through silicon vias instead of wires.

The buffer chips BF may be a chip that mediates signal exchange between the device controller 110 and the memory chips MC. The buffer chips BF may be connected to upper bonding pads BP1 through a third wire W3. In some embodiments, the buffer chips BF may be flip-chip bonded on the package substrate 125. The buffer chips BF may be electrically connected to an external device controller 110 through first connection wire RDL1 to exchange signals. First connections RDL1 may provide a signal path between the device controller 110 and the buffer chips BF. Second connections RDL2 may provide a signal path between the buffer chips BF and the memory chips MC.

According to an example embodiment, the memory packages 120A and 120B may include a pair of buffer chips BF corresponding to respective groups G1 and G2 of the memory chips MC. The buffer chips BF mounted in the first memory package 120A may communicate with the device controller 110 through a first channel CH1. The buffer chips BF mounted in the second memory package 120B may communicate with the device controller 110 through a second channel CH2. Therefore, a stub length in a signal transmission path (single channel) of the device controller 110 and the buffer chips BF may be reduced, and signal reflection and RC delay may be minimized.

Each of the memory packages 120A and 120B may include a first buffer chip 121 that mediates signal exchange between the memory chips of a first group G1 and the device controller 110, and a second buffer chip 122 that mediates signal exchange between the memory chips of a second group G2 and the device controller 110. The first buffer chip 121 and the second buffer chip 122 may be connected to the first connections RDL1 through some of the upper bonding pads BP1 arranged between the first buffer chip 121 and the second buffer chip 122. The stub path of the first connections RDL1 may be formed only between the pair of buffer chips BF.

Referring to FIG. 7B, the storage device 100B′ of the example embodiment may have the same or similar features as those described with reference to FIG. 7A, except that the memory packages 120A and 120B mounted on opposite sides (e.g., an upper surface and a lower surface) of the system substrate 101 are connected to the same channel. The interconnections INC of the system substrate 101 may be connected to the device controller 110 and the memory packages 120A and 120B through the interconnection pads 101P1 and 101P2. The device controller 110 and the memory packages 120A and 120B may be electrically connected with each other through the interconnections INC formed inside the system substrate 101 to exchange signals. According to the example embodiment, the device controller 110 may communicate with the first and second memory packages 120A and 120B through a single channel. For example, the device controller 110 may communicate with the first memory package 120A and the second memory package 120B through a first channel CH1 provided by the interconnections INC. The first memory package 120A and the second memory package 120B may communicate with the device controller 110 using the same single channel (e.g., the first channel CH1). As a result, a stub path length of the channel may be reduced, and SI (Signal Integrity) characteristics of the storage device may be improved. As such, when a branch point of the channel path connecting the device controller 110 and the plurality of buffer chips BF is formed inside the package substrate 125 while a gap between the plurality of buffer chips BF is minimized (i.e., a length of the stub path is minimized), an input/output speed between the device controller 110 and the memory packages 120A and 120B may be improved by about 10% or more compared to the case where the branch point of the channel path is formed inside the system substrate 101.

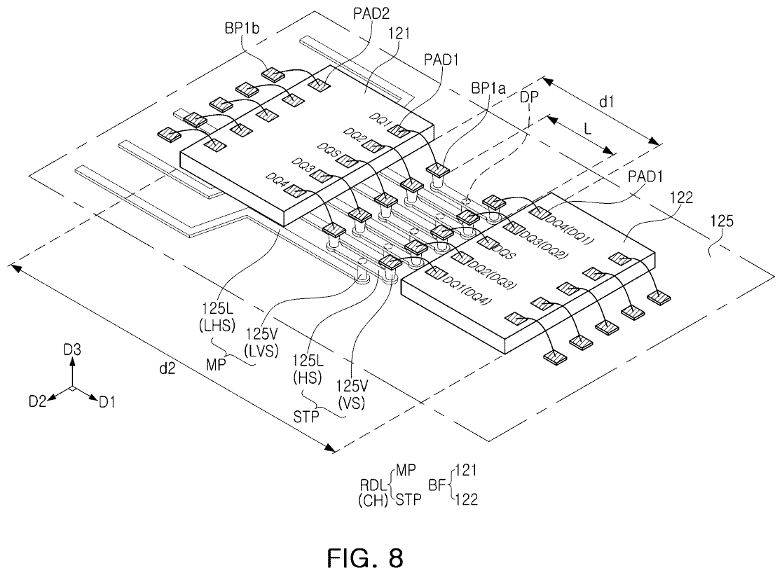

FIG. 8 is a schematic diagram of buffer chips BF according to an example embodiment.

Referring to FIG. 8, the buffer chips BF of the example embodiment may be arranged in at least one pair. For example, the buffer chips BF may include a first buffer chip 121 and a second buffer chip 122 that are arranged adjacently in a first horizontal direction D1 which is parallel to an upper surface of the system substrate 101 or an upper surface of a package substrate 125. The first buffer chip 121 and the second buffer chip 122 may be connected to connections RDL of the package substrate 125 through first upper bonding pads BP1a arranged between the buffer chips BF.

The connections RDL may provide a channel path CH between the buffer chips BF and an external device controller. The channel path CH may include a main path MP extending from the external device controller to a branch point DP between the buffer chips BF and a stub path STP branching from the main path MP and connected to the first buffer chip 121 and the second buffer chip 122. The main path MP and the stub path STP may be provided by a connection pattern 125L and/or a connection via 125V of the package substrate 125. The channel path CH may include a plurality of main paths MP and a plurality of stub paths STP, and the plurality of stub paths STP may be spaced apart from each other in a second horizontal direction D2 parallel to the upper surface of the system substrate 101 or the upper surface of a package substrate 125. The second horizontal direction D2 may be perpendicular to the first horizontal direction D1.

In an embodiment, the stub path STP may include a horizontal section HS provided by the connection pattern 125L and vertical sections VS provided by the connection via 125V. The horizontal section HS may extend horizontally from the branch point DP and may have opposite ends connected to the corresponding first upper bonding pads BP1a, respectively. The vertical sections VS may extend vertically from the opposite ends of the horizontal section HS to the corresponding first upper bonding pads BP1a. Opposite ends of the connection pattern 125L providing the horizontal section HS may be located at the same vertical level. The main path MP may include a lower horizontal section LHS provided by the connection pattern 125L and a lower vertical section LVS provided by the connection via 125V. The branch point DP may be defined as a contact region where the lower vertical section LVS is connected to (or contacts) the horizontal section HS. The branch point DP may be located in the middle, in the first horizontal direction D1, of the connection pattern 125L providing the horizontal section HS. Lengths of the connection patterns 125L providing the horizontal section HS may be constant or may be the same as each other, and heights of the connection vias 125V providing the vertical sections VS extending from the branch points DP to the first upper bonding pads BP1a may be constant or may be the same as each other.

The connection pattern 125L providing the horizontal section HS may be located between the first buffer chip 121 and the second buffer chip 122. The first buffer chip 121 and the second buffer chip 122 may include one sides (hereinafter, referred to as “inner surfaces”) facing each other in the first horizontal direction D1 and the other sides (hereinafter, referred to as “outer surfaces”) facing opposite to the one sides. A length L of the horizontal section HS in the first horizontal direction D1 may be less than a distance d1, in the first horizonal direction D1, between the inner surfaces of the pair of buffer chips BF or a distance d2, in the first horizontal direction D1, between the outer surfaces of the pair of buffer chips BF. The connection pattern 125L providing the horizontal section HS may not overlap the first buffer chip 121 and the second buffer chip 122 in a vertical direction D3 perpendicular to the upper surface of the package substrate 125. According to an example embodiment, a stub length (the length of the horizontal section HS) among the signal transmission paths (single channel) of the device controller 110 and the buffer chips BF may be reduced, and signal reflection and RC delay may be minimized.

In an example embodiment, one of the pair of buffer chips BF may be configured to mirror a data signal of the external device controller transmitted through the channel path CH. The pair of buffer chips BF may be adjacent so that their respective one sides, where controller connection pads PAD1 are arranged, face each other. When the pair of buffer chips BF have the same arrangement of controller connection pads PAD1, the arrangement order of the controller connection pads PAD1 arranged to face each other may be reversed. For example, the first buffer chip 121 has a pad configuration of the controller connection pads PAD1 in a sequence of data pads DQ1, DQ2, DQs, DQ3, and DQ4 while the second buffer chip 122 has a pad configuration of the controller connection pads PAD1 in an opposite sequence of data pads DQ4, DQ3, DQS, DQ2, and DQ1. In this case, a routing length may be lengthened in order to match the order of the data pads. However, according to one embodiment, one of the buffer chips BF may be configured to mirror the data signal path (i.e., the pad configuration of the controller connection pads PAD1 and a signal path connected thereto), thereby each of the first and second buffer chips 121 and 122 having the same sequence of data pads DQ1, DQ2, DQS, DQ3, and DQ4. Such a mirrored signal path may enable a routing design between the first upper bonding pads BP1a arranged in two rows to be simplified, and consequently shorten the stub path STP of the channel path CH. In other words, the arrangement of the controller connection pads PAD1 of the first buffer chip 121 and the arrangement of the controller connection pads PAD1 of the second buffer chip 122 may be in a mirror-symmetry with respect to a space between the first and second buffer chips 121 and 122.

The pair of buffer chips BF may be designed so that the controller connection pads PAD1 are symmetrical with respect to a data strobe signal pin DQS and data pins DQ1, DQ2, DQ3 and DQ4 that require high-speed operations. For example, a power pin, a ground pin, a chip enable signal pin, a command latch enable signal pin, an address latch enable signal pin, a write enable signal pin, a read enable signal pin, a ready busy signal pin, or a select signal pin may be arranged symmetrically with respect to the data strobe signal pin DQS and the data pins DQ1, DQ2, DQ3 and DQ4.

For example, when the first buffer chip 121 is arranged at 0 degrees and the second buffer chip 122 is arranged at 180 degrees, the orders of the data pins DQ1, DQ2, DQ3 and DQ4 of the first buffer chip 121 and the data pins DQ1, DQ2, DQ3 and DQ4 of the second buffer chip 122 may be reversed. The second buffer chip 122 may have a DQ mirroring function that exchanges bit 0 with 7, 1 with 6, 2 with 5, and 3 with 4. The second buffer chip 122 may form a mirror signal of a data signal input from the external device controller. The present disclosure is not limited thereto. In an embodiment, the second buffer chip 122 may have a physical layout and a signal routing which is a mirror image of the first buffer chip 121 for signal integrity. The second buffer chip 122 does not have a DQ mirroring function.

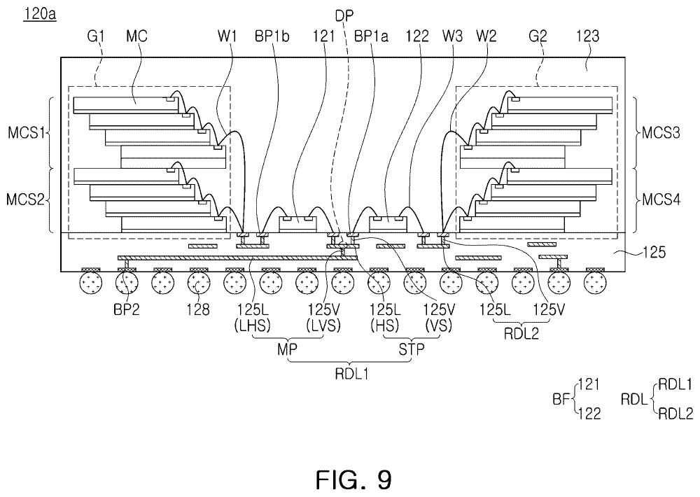

FIG. 9 is a cross-sectional side view of a memory package 120a according to an example embodiment.

Referring to FIG. 9, the memory package 120a of the example embodiment may include a plurality of memory chips MC, a plurality of buffer chips BF, and a package substrate 125. The plurality of buffer chips BF and the plurality of memory chips MC may be covered with a protective layer 123 above the package substrate 125.

The plurality of memory chips MC may be vertically stacked in a step shape on a package substrate 125. The plurality of memory chips MC may be divided into a plurality of groups G1 and G2 and respectively connected to the plurality of buffer chips BF, and the plurality of buffer chips BF may each respectively assign channels to the plurality of groups G1 and G2 to mediate signal transmission and reception with an external device controller. As an example, the memory chips MC of the first and second groups G1 and G2 may be connected to a first buffer chip 121 and a second buffer chip 122, respectively. Semiconductor chips of the first group G1 may be connected to the first buffer chip 121 through a first wire W1, and semiconductor chips of the second group G2 may be connected to the second buffer chip 122 a second wire W2. In some embodiments, the first wire W1 and the second wire W2 may be directly connected to memory access pads of the buffer chips BF without passing through second connections RDL2.

The plurality of buffer chips BF may mediate signal exchange between the memory chips MC of the corresponding groups G1 and G2 and the device controller 110, respectively. The plurality of buffer chips BF may activate at least some of the plurality of memory chips MC based on address information received from the external device controller. For example, the first group G1 may include a first memory chip set MCS1 and a second memory chip set MCS2, and the second group G2 may include a third memory chip set MCS3 and a fourth memory chip set MCS4. The first buffer chip 121 may activate or deactivate the first memory chip set MCS1 and/or the second memory chip set MCS2 of the first group G1 based on the address information received from the external device controller. The second buffer chip 122 may activate or deactivate the third memory chip set MCS3 and/or the fourth memory chip set MCS4 of the second group G2 based on the address information received from the external device controller.

The plurality of buffer chips BF may be electrically connected to the memory chips MC and the external device controller through connections RDL. First connections RDL1 may connect the first upper bonding pads BP1a and the lower bonding pads BP2, and may provide a main path MP and a stud path STP through which the external device controller and the plurality of buffer chips BF exchange signals through package bumps 128.

The stub path STP may include a horizontal section HS provided by a connection pattern 125L and vertical sections VS provided by a connection via 125V. The horizontal section HS may extend horizontally from a branch point DP and have opposite ends connected to the corresponding first upper bonding pads BP1a, respectively. The vertical sections VS may extend vertically from the opposite ends of the horizontal section HS to the corresponding first upper bonding pads BP1a. Opposite ends of the connection pattern 125L providing the horizontal section HS may be located at the same vertical level. The main path MP may include a lower horizontal section LHS provided by the connection pattern 125L and a lower vertical section LVS provided by the connection via 125V. The branch point DP may be defined as a contact region where the lower vertical section LVS is connected to (or contacts) the horizontal section HS. The branch point DP may be located in the middle of the connection pattern 125L providing the horizontal section HS.

The connection pattern 125L providing the horizontal section HS may be located between the first buffer chip 121 and the second buffer chip 122. The connection pattern 125L providing the horizontal section HS may not overlap with the first buffer chip 121 and the second buffer chip 122 in a vertical direction D3. According to the example embodiment, a stub length (length of the horizontal section HS) among the signal transmission paths (single channel) of the device controller 110 and the buffer chips BF may be reduced, and signal reflection and RC delay may be minimized.

FIG. 10 is a cross-sectional view of a memory package 120b according to the example embodiment.

Referring to FIG. 10, the memory package 120b of the example embodiment may have the same or similar features as those described with reference to FIG. 9, except for the stub path STP. The stub path STP may include only the horizontal section HS provided by the connection pattern 125L. The stub path STP may be located at the same vertical level as the first upper bonding pads BP1a. The stub path STP may overlap the first upper bonding pads BP1a in the horizontal direction D1. The stub path STP may extend horizontally from the branch point DP and have opposite ends that contact the corresponding first upper bonding pads BP1a, respectively. Opposite ends of the horizontal section HS that contact the first upper bonding pads BP1a may be located at the same vertical level. As such, a length of the stub path STP may be minimized, and SI characteristics may be further improved.

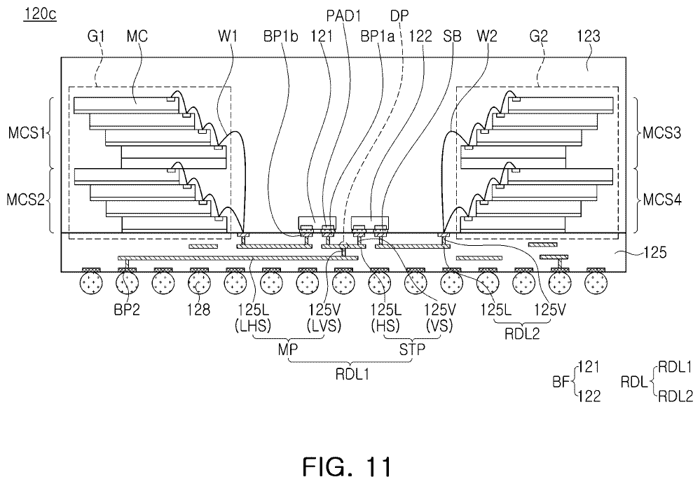

FIG. 11 is a cross-sectional side view of a memory package 120c according to an example embodiment.

Referring to FIG. 11, the memory package 120c of the example embodiment may have the same or similar features as those described with reference to FIGS. 9 and 10, except that the buffer chip BF is flip-chip bonded. The buffer chip BF may be connected to the connections RDL via a conductive bump SB. The conductive bump SB may be arranged between the controller connection pad PAD1 and the first upper bonding pads BP1a, and between the memory connection pad PAD2 and the second upper bonding pads BP1b. The stub path STP may be formed between the outer surfaces of the buffer chips BF. The stub path STP may partially overlap the first buffer chip 121 and the second buffer chip 122 in the vertical direction D3, respectively. The connection pattern 125L providing the horizontal section HS of the stub path STP may be extended further than a distance between the inner surfaces of the first buffer chip 121 and the second buffer chip 122.

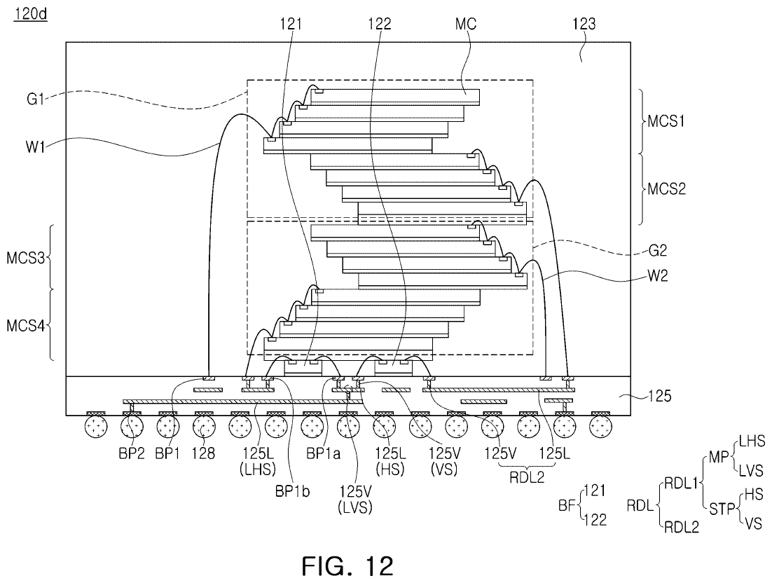

FIG. 12 is a cross-sectional side view of a memory package 120d according to an example embodiment.

Referring to FIG. 12, the memory package 120d of the example embodiment may have the same or similar features as those described with reference to FIGS. 9 to 11, except for a stacking form of the plurality of memory chips MC. The plurality of memory chips MC may be stacked in a vertical direction perpendicular to an upper surface of a package substrate 125 on at least one pair of buffer chips BF. For example, the memory chips of the first group G1 and the second group G2 may be stacked in the vertical direction on the first buffer chip 121 and the second buffer chip 122. The memory chips MC of the first group G1 and the second group G2 may be stacked in a step shape with steps formed between each other so that each chip pad is exposed. The first group G1 may be connected to second upper bonding pads BP1b through the first wire W1, and the second group G2 may be connected to the second upper bonding pads BP1b through the second wire W2. The first memory chip set MCS1 and the second memory chip set MCS2 may be arranged so that each chip pad faces opposite to each other. The third memory chip set MCS3 and the fourth memory chip set MCS4 may be arranged so that each chip pad faces opposite to each other.

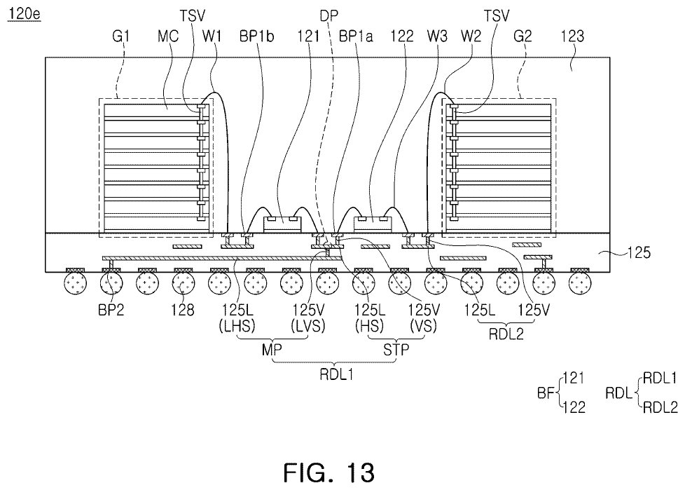

FIG. 13 is a cross-sectional side view of a memory package 120e according to an example embodiment.

Referring to FIG. 13, the memory package 120e of the example embodiment may have the same or similar features as those described with reference to FIGS. 9 to 12, except for a stacking form of the plurality of memory chips MC. The memory chips MC in each of the first and second groups G1 and G2 may be stacked without a step between each other. The memory chips MC may be arranged so that each chip pad overlaps another memory chip MC that is vertically adjacent. The memory chips MC may be interconnected via a through silicon via TSV rather than a wire. Unlike the through interconnections 218 illustrated in FIG. 2, the through silicon via TSV may directly connect the stacked memory chips MC to each other. The memory chips MC of the first group G1 may be interconnected through the through silicon via TSV and connected to the second connection wire RDL2 through the first wire W1. The memory chips MC of the second group G2 may be interconnected via a through silicon vias TSV and connected to the second connections RDL2 through the second wire W2.

FIG. 14 is a cross-sectional side view of a memory package 120f according to an example embodiment.

Referring to FIG. 14, the memory package 120f of the example embodiment may have the same or similar features as those described with reference to FIGS. 9 to 13, except for a connection method of the memory chips MC and the connections RLD. The memory chips MC may be connected to the second connections RDL2 without a wire. The memory chips of the first group G1 and the second group G2 may be interconnected via through silicon vias TSV and directly connected to the second upper bonding pads BP1b. A signal path between the memory chips MC and the buffer chip BF may be shortened.

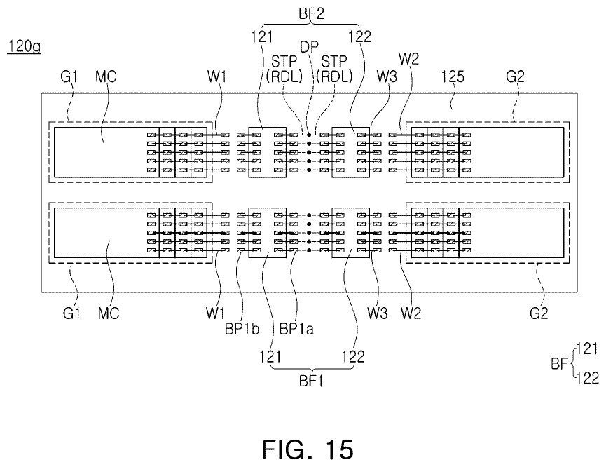

FIG. 15 is a cross-sectional side view of a memory package 120g according to an example embodiment.

Referring to FIG. 15, the memory package 120g of the example embodiment may have the same or similar features as those described with reference to FIGS. 9 to 14, except for the number of buffer chips BF. The memory package 120g may include a first pair of buffer chips BF1 and a second pair of buffer chips BF2, each of which is composed of a pair of buffer chips BF. The first pair of buffer chips BF1 and the second pair of buffer chips BF2 may be connected to the connections RDL of a package substrate 125 in a similar manner as described in FIG. 8. The first pair of buffer chips BF1 and the second pair of buffer chips BF2 may include a first buffer chip 121 and a second buffer chip 122, which are connected to an external device controller through the same channel, respectively. As such, the memory package of the example embodiment may include a greater number of buffer chips BF and memory chips MC than those illustrated in the drawing.

According to embodiments of the example embodiments, a memory package and storage device may be provided that effectively connect multiple memory chips using a plurality of buffer chips.

The various advantageous and beneficial effects of the example embodiments are not limited to the above-described contents, and will be more easily understood in the process of explaining specific embodiments of the example embodiments.

However, the effects of the example embodiments are not limited to the effects described above, and may be expanded in various ways without departing from the spirit and scope of the example embodiments.

While example embodiments have been shown and described above, it will be apparent to those skilled in the art that modifications and variations could be made without departing from the scope of the example embodiments as defined by the appended claims.

What is claimed is:

1. A memory package comprising:
a package substrate;
a plurality of memory chips disposed on an upper surface of the package substrate and grouped into a first group of memory chips stacked in a vertical direction perpendicular to the upper surface of the package substrate and a second group of memory chips stacked in the vertical direction, wherein the first group of memory chips are spaced apart from the second group of memory chips in a first horizontal direction parallel to the upper surface of the package substrate;
a first buffer chip disposed on the upper surface of the package substrate and configured to output a control command signal received from an external memory controller to the first group of memory chips; and
a second buffer chip disposed on the upper surface of the package substrate and configured to output the control command signal to the second group of memory chips, wherein the first buffer chip and the second buffer chip are disposed in a space between the first group of memory chips and the second group of memory chips and arranged in the first horizontal direction,
wherein the package substrate includes:
a main path through which the control command signal is transmitted from the external memory controller, and
a stub path connecting the main path to each of the first buffer chip and the second buffer chip,
wherein the stub path is configured to branch the control command signal received from the main path to the first buffer chip and the second buffer chip, and
wherein the stub path, when view in a plan view, is disposed in a space between the first buffer chip and the second buffer chip.

2. The memory package of claim 1,
wherein the stub path comprises a horizontal section extending in the first horizontal direction,
wherein opposite ends of the horizontal section are respectively connected to the first buffer chip and the second buffer chip, and
wherein a length, in the first horizontal direction, of the horizontal section is less than a distance, in the first horizontal direction, between the first buffer chip and the second buffer chip.

3. The memory package of claim 2,
wherein an end of the main path is connected to a middle, in the first horizontal direction, of the opposite ends of the horizontal section.

4. The memory package of claim 1, further comprising:
a plurality of first upper bonding pads are arranged in a second horizontal direction parallel to the upper surface of the package substrate and perpendicular to the first horizontal direction, wherein the plurality of first upper bonding pads are connected to the stub path; and
a plurality of second upper bonding pads are arranged in the second horizontal direction, wherein the plurality of second upper bonding pads are connected to the stub path,
wherein the plurality of first upper bonding pads and the plurality of second upper bonding pads, when viewed in the plan view, are disposed in the space between the first buffer chip and the second buffer chip,
wherein the first buffer chip is connected to the stub path through the plurality of first upper bonding pads, and
wherein the second buffer chip is connected to the stub path through the plurality of second upper bonding pads.

5. The memory package of claim 1,
wherein the first buffer chip comprises:
a plurality of first controller connection pads connected to the external memory controller and arranged in a second horizontal direction parallel to the upper surface of the package substrate and perpendicular to the first horizontal direction; and
a plurality of first memory connection pads connected to the first group of memory chips and arranged in the second horizontal direction, and
wherein the plurality of first controller connection pads, when viewed in the plan view, are disposed between the plurality of first memory connection pads and the space between the first buffer chip and the second buffer chip.

6. The memory package of claim 5,
wherein the first buffer chip is configured to receive the control command signal through the plurality of first controller connection pads.

7. The memory package of claim 6,
wherein the second buffer chip comprises:
a plurality of second controller connection pads connected to the external memory controller and arranged in the second horizontal direction; and
a plurality of second memory connection pads connected to the second group of memory chips and arranged in the second horizontal direction,
wherein the plurality of second controller connection pads, when viewed in the plan view, are disposed between the space between the first buffer chip and the second buffer chip and the plurality of second memory connection pads,
wherein the second buffer chip receives the control command signal from the plurality of second controller connection pads,
wherein the plurality of first controller connection pads and the plurality of second controller connection pads are disposed in a space between the plurality of first memory connection pads and the plurality of second memory connection pads,
wherein one of the first buffer chip and the second buffer chip is configured to mirror a data signal in response to the received control command signal, and
wherein the first buffer chip and the second buffer chip have signal paths, in a mirror-symmetry, connected the plurality of first controller connection pads and the plurality of second controller connection pads.

8. The memory package of claim 1, further comprising:
a system substrate on which the package substrate and the external memory controller are mounted.

9. The memory package of claim 8,
wherein the system substrate comprises a plurality of interconnections electrically connected to the main path of the package substrate.

10. The memory package of claim 1,
wherein the stub path includes:
a horizontal section extending in the first horizontal direction; and
a pair of vertical sections erected from the horizontal section in the vertical direction,
wherein the pair of vertical sections are connected to the first buffer chip and the second buffer chip, respectively, and
wherein a middle, in the first horizontal direction, of the horizontal section is connected to the main path.

11. A storage device comprising:
a system substrate comprising a plurality of interconnections;
a memory controller mounted on the system substrate; and
at least one memory package mounted on the system substrate and configured to operate in response to a control command signal received from the memory controller through the plurality of interconnections,
wherein the at least one memory package comprises:
a plurality of memory chips;
a pair of buffer chips adjacent to each other in a first horizontal direction parallel to an upper surface of the system substrate, connected to the memory controller and the plurality of memory chips, and configured to output the control command signal received from the memory controller to the plurality of memory chips;
a package substrate comprising a plurality of connections electrically connected to the plurality of interconnections, and a plurality of upper bonding pads between the pair of buffer chips and electrically connected to the pair of buffer chips, wherein the plurality of memory chips and the pair of buffer chips are mounted on the package substrate; and
a protective layer encapsulating the plurality of memory chips and the pair of buffer chips,
wherein the pair of buffer chips are connected to the memory controller through a single channel provided by the plurality of interconnections and the plurality of connections,
wherein the single channel comprises a main path connected to the memory controller, and a stub path extending from one end of the main path located between the pair of buffer chips and connected to each buffer chip of the pair of buffer chips,
wherein the stub path comprises a horizontal section extending from the one end of the main path in the first horizontal direction and having opposite ends respectively connected to corresponding upper bonding pads of the plurality of upper bonding pads,
wherein the one end of the main path is connected to a middle, in the first horizontal direction, of the opposite ends of the horizontal section of the stub path, and
wherein the opposite ends of the horizontal section of the stub path are at the same vertical level in a vertical direction perpendicular to the upper surface of the system substrate.

12. The storage device of claim 11,
wherein the pair of buffer chips comprise one sides facing each other in the first horizontal direction and the other sides facing opposite to the one sides, and
wherein a length, in the first horizontal direction, of the horizontal section of the stub path is less than a distance, in the first horizontal direction, between the one sides or a distance, in the first horizontal direction, between the other sides.

13. The storage device of claim 11,
wherein the main path comprises a lower horizontal section arranged below the horizontal section of the stub path, and a lower vertical section extending in the vertical direction and connecting the lower horizontal section to the horizontal section of the stub path, and
wherein the one end of the main path corresponds to an upper end of the lower vertical section contacting the horizontal section of the stub path.

14. The storage device of claim 13,
wherein the plurality of connections include a connection pattern providing the horizontal section and the lower horizontal section, and a connection via providing the lower vertical section.

15. The storage device of claim 11,
wherein the single channel includes a plurality of main paths and a plurality of stub paths extending from the plurality of main paths, and
wherein the plurality of stub paths include a plurality of horizontal sections spaced apart from each other in a second horizontal direction parallel to the upper surface of the system substrate and perpendicular to the first horizontal direction.

16. The storage device of claim 11,
wherein the stub path further comprises a pair of vertical sections extending in the vertical direction from the opposite ends of the horizontal section to a corresponding pair of upper bonding pads of the plurality of upper bonding pads.

17. The storage device of claim 11,
wherein the horizontal section of the stub path is located at the same vertical level in the vertical direction as the plurality of upper bonding pads, and
wherein the horizontal section includes opposite ends contacting corresponding upper bonding pads of the plurality of upper bonding pads.

18. The storage device of claim 11,
wherein the pair of buffer chips comprise a first buffer chip and a second buffer chip,
wherein the plurality of memory chips comprise a first group of memory chips connected to the first buffer chip, and a second group of memory chips connected to the second buffer chip,
wherein the first buffer chip transmits a first control signal branched from the control command signal at a contact region where the main path is connected to the stub path to the first group of memory chips, and
wherein the second buffer chip transmits a second control signal branched from the control command signal at the contact region to the second group of memory chips.

19. A storage device comprising:
a system substrate;
a memory controller mounted on the system substrate; and
at least one memory package mounted on the system substrate and configured to operate in response to a control command signal received from the memory controller,
wherein the at least one memory package comprises:
a plurality of memory chips;
a pair of buffer chips arranged adjacently to each other, connected to the memory controller and the plurality of memory chips, and configured to output the control command signal received from the memory controller to the plurality of memory chips; and
a package substrate comprising a pair of upper bonding pads electrically connected to the pair of buffer chips,
wherein the plurality of memory chips and the pair of buffer chips are mounted on the package substrate,
wherein the pair of buffer chips are connected to the memory controller through a main path extending from the memory controller and a stub path extending from the main path, and
wherein the stub path contacts the pair of upper bonding pads between the pair of buffer chips.

20. The storage device of claim 19,
wherein a branch point where the stub path is connected to the main path is located within the package substrate, and
wherein a length of the stub path from the branch point to one of the pair of upper bonding pads is the same as a length of the stub path from the branch point to the other of the pair of upper bonding pads.
